(19) United States
(12) Patent Application Publication
(10) Pub. No.: US 2016/0157339 A1
(43) Pub. Date: Jun. 2, 2016

(54) SERVER

(71) Applicants: Inventec (Pudong) Technology Corporation, Shanghai (CN); INVENTEC CORPORATION, Taipei City (TW)

(72) Inventors: Hsiao-Ching HSU, Taipei City (TW); Kuei-Hau CHEN, Taipei City (TW)

(21) Appl. No.: 14/674,864

(22) Filed: Mar. 31, 2015

(30) Foreign Application Priority Data
Nov. 27, 2014 (CN) 201410709853.2

(51) Int. Cl. H05K 1/02

(52) U.S. Cl. CPC H05K 1/0271; H05K 1/0203; H05K 2201/066

(57) ABSTRACT

A server includes a printed circuit board, a heat sink and a rigid rod. The printed circuit board has a stress concentration zone and a stress dispersion zone around the stress concentration zone. The heat sink is connected to the printed circuit board and located on the stress concentration zone. The rigid rod is connected to the heat sink and fixed on the printed circuit board, and extended across the stress concentration zone and fixed on the stress dispersion zone, so as to reduce the stress forced on the stress concentration zone.

### FIELD OF THE INVENTION

The present invention is related to a server, and more particularly related to a server utilizing a rigid rod connected to a heat sink to reinforce the printed circuit board.

### BACKGROUND OF THE INVENTION

In general, to prevent the printed circuit board of the printed circuit board assembly (PCBA) from being bended because of dropping or vibrating during the shipment, it is a typical method that an iron back plate disposed on the printed circuit board in order to enhance the strength of the printed circuit board.

Please refer to FIG. 1, which is a perspective schematic view showing a prior art printed circuit board assembly with an iron back plate. As shown, the printed circuit board assembly PA100 includes a printed circuit board PA1 and an iron back plate PA2. The iron back plate PA2 is an iron frame with a central opening. The iron back plate PA2 is fixed to the printed circuit board PA1 by using four screws PA200. In practice, it is high possible that the iron back plate PA2 is screw-fixed to the heat sink (not shown) on the other side of the printed circuit board PA1 so as to have the printed circuit board PA1 fixed between the iron back plate PA2 and the heat sink.

As mentioned above, the iron back plate PA2 fixed to the printed circuit board PA1 can be used to support the printed circuit board PA1 and prevent the printed circuit board PA1 from being bended as being dropped or shocked. However, to make sure that the strength of the printed circuit board PA1 can be enhanced with the help of the iron back plate PA2, the iron back plate PA2 must be directly attached to the printed circuit board PA1. Thus, a great portion of the surface area on the printed circuit board PA1, which can be used for locating the electronic elements, must be left empty for the purpose of attaching the iron back plate PA2 such that the applicable layout area on the printed circuit board PA1 would be influenced. In addition, if there are lots of electronic elements to be located on the printed circuit board PA1, it would be difficult to further assemble the iron back plate PA2 to enhance the strength of the printed circuit board PA1.

### BRIEF SUMMARY OF INVENTION

In view of the prior art, when using the iron back plate to enhance the strength of the printed circuit board, the layout of electronic elements on the printed circuit board may suffer the restriction due to the area occupied by the iron back plate. In addition, such method might not be useful to the printed circuit board without sufficient empty area.

Accordingly, it is a main object of the present invention to provide a server, which can enhance the strength of the printed circuit board effectively without occupying too much surface area.

To resolve the problem of the conventional art, a server is provided in accordance with an embodiment of the present invention. The server includes a printed circuit board, a heat sink, and a rigid rod. The printed circuit board has a stress concentration zone and a stress dispersion zone around the stress concentration zone. The heat sink is connected to the printed circuit board. The rigid rod is connected to the heat sink and is fixed to the two sides of the printed circuit board. Because the rigid rod is fixed to the two sides of the printed circuit board, when suffering an impact, the rigid rod can support the printed circuit board to withstand the impact and prevent the printed circuit board from being deformed. In addition, because the rigid rod is connected to the heat sink, the impact to the rigid rod can be dispersed to the heat sink such that the ability to withstand the impact can be further improved.

In accordance with an embodiment of the present invention, the rigid rod includes a rod body, which is connected to the heat sink. As a preferred embodiment, the rod body is connected to the heat sink by welding. The rigid rod has two end fixing parts. The two end fixing parts are located on two ends of the rod body and fixed on the stress dispersion zone respectively. In addition, each of the two end fixing parts has a screw hole for fixing the end fixing parts to the two sides of the printed circuit board. To connect the heat sink and the rigid rod body by welding can strengthen the connection between the rigid rod and the heat sink. In addition, the screw holes on the rigid rod are helpful for fixing the rigid rod to the printed circuit board effectively and rapidly.

In accordance with an embodiment of the present invention, the heat sink has a plurality of heat dissipation fins so as to remove the heat on the printed circuit board effectively.

In accordance with an embodiment of the present invention, the heat sink has a plurality of fixing holes for fixing the heat sink to the stress concentration zone of the printed circuit board such that the heat sink can be effectively fixed on the printed circuit board.

In accordance with an embodiment of the present invention, the heat sink is made of metal material with a high thermal conductivity such that the heat generated on printed circuit board can be effectively removed.

The embodiments adopted in the present invention would be further discussed by using the flowing paragraph and the figures for a better understanding.

### BRIEF DESCRIPTION OF THE DRAWINGS

FIG. 1 is a 3D schematic view showing the printed circuit board assembly with a iron back plate;

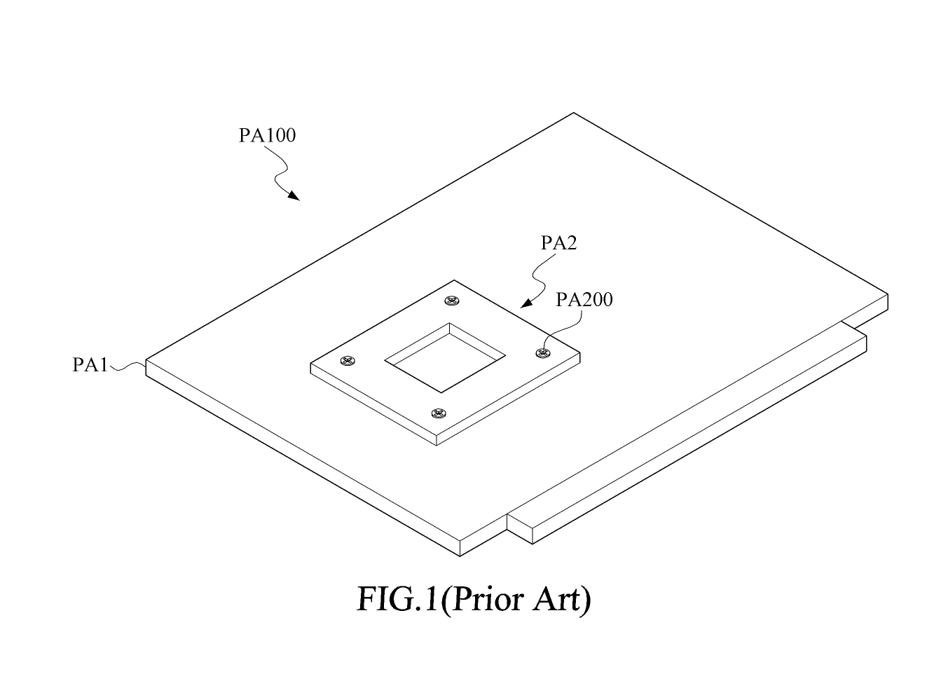

FIG. 2 is a 3D schematic view showing the server provided in accordance with a preferred embodiment of the present invention; and

FIG. 3 is a schematic view showing the heat sink and the rigid rod provided in accordance with a preferred embodiment of the present invention.

### DETAILED DESCRIPTION OF THE INVENTION

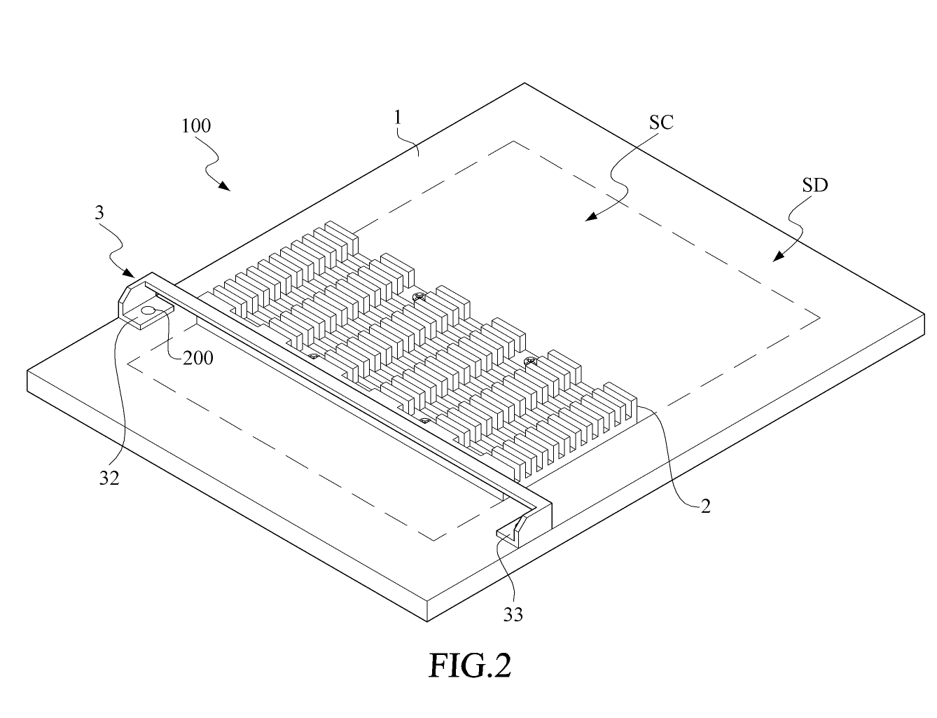

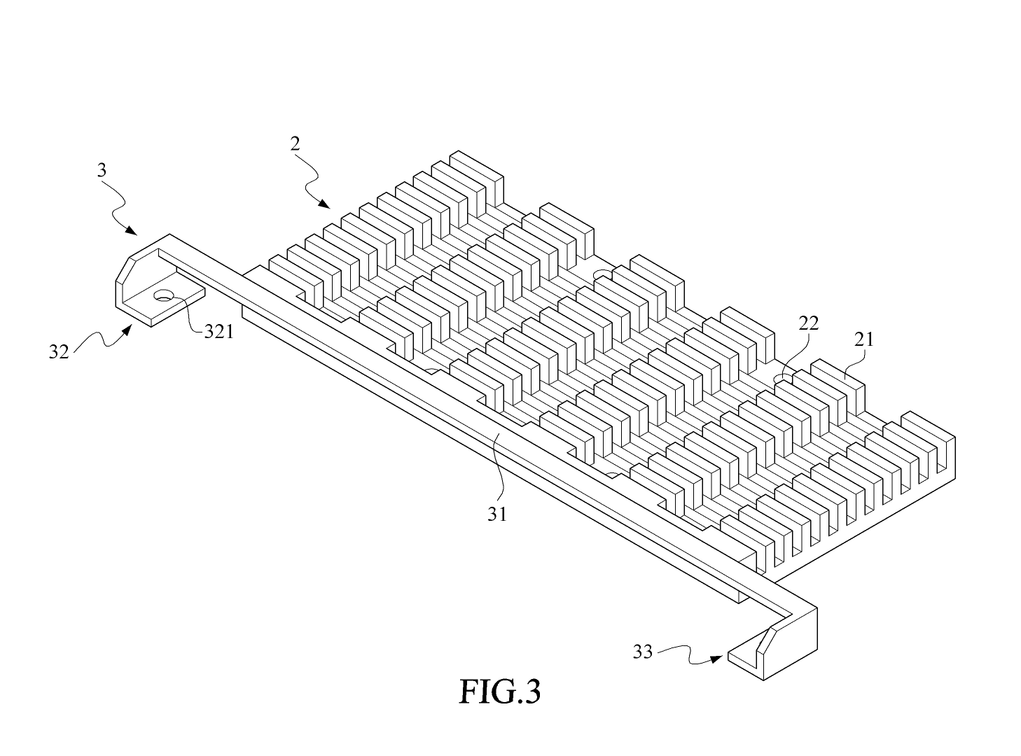

Please refer to FIG. 2 and FIG. 3, wherein FIG. 2 is a 3D schematic view showing the server provided in accordance with a preferred embodiment of the present invention and FIG. 3 is a schematic view showing the heat sink and the rigid rod provided in accordance with a preferred embodiment of the present invention. As shown, the server 100 includes a printed circuit board 1, a heat sink 2, and a rigid rod 3. The printed circuit board 1 includes a stress concentration zone SC and a stress dispersion zone SD around the stress concentration zone SC.

The heat sink 2 is composed of a plurality of heat dissipation fins 21 and the heat sink 2 has four fixing holes 22 (only one of them is labeled). The heat sink 2 can be made of materials with high thermal conductivity, such as Aluminum, Copper, or other metal materials.

The rigid rod 3 includes a rod body 31 and two end fixing parts 32 and 33. The rod body 31 is connected to the heat sink 2 by welding. The two end fixing parts 32 and 33 are located on two ends of the rod body 31, wherein the end fixing part 32 has a screw hole 321 and the end fixing part 33 also has a screw hole (not labeled, but the position is corresponded to the screw hole 321). The rigid rod 3 is made of rigid metal material, such as stainless steel.

In practical application, the heat sink 2 in the server 100 is screw-fixed to the stress concentration zone SC of the printed circuit board 1 with the help of the fixing holes 22 of the heat sink 2. For example, there may be screw holes formed in the stress concentration zone SC of the printed circuit board 1 corresponding to the fixing holes 22. The screws to be fixed in the screw hole can penetrate the fixing hole 22 first to have the heat sink 2 screw-fixed to the stress concentration zone SC of the printed circuit board 1. The heat sink 2 may be partially attached to the printed circuit board 1 in practice to have the heat generated by the printed circuit board 1 successfully transferred to the heat dissipation fins 21 through the contact portion rather than having the overall structure attached to the printed circuit board 1. In practice, the heat sink 2 is made of metal material with high thermal conductivity, such as Aluminum or Copper. However, the present invention is not so restricted.

In addition, the two end fixing parts 32 and 33 of the rigid rod 3 are screw-fixed on the stress dispersion zone SD by using two screws 200 corresponding to the screw hole 321 on the end fixing part 32 and the other screw hole on the end fixing part 33. For example, there may be through holes corresponding to the screw holes 321 formed in the stress dispersion zone SD of the printed circuit board 1 such that the screws to be fixed in the screw holes 321 can penetrate the through holes first to have the two end fixing parts 32 and 33 screw-fixed to the printed circuit board 1. The way of fixing the rigid rod 3 to the printed circuit board 1 by using the screws can have the rigid rod 3 effectively and rapidly fixed to the printed circuit board 1.

As mentioned, because the rigid rod 3 is fixed to the heat sink 2, the heat sink 2 is fixed to the stress concentration zone SC of the printed circuit board 1, and the rigid rod 3 is also fixed to the stress dispersion zone SD of the printed circuit board 1, the printed circuit board 1 would be widely supported by the heat sink 2 and the rigid rod 3 such that the overall strength of the printed circuit board 1 can be enhanced.

In conclusion, because the conventional art relies on the strength of the iron back plate to strengthen the printed circuit board, the iron back plate should be attached and fixed to the printed circuit board to make sure that the strength of the printed circuit board can be enhanced. That is, the strength of the printed circuit board is decided by the area on the printed circuit board occupied by the iron back plate. In order to reduce the area needed for attaching the iron back plate, the frame-shaped iron back plate was provided in accordance with the prior art. However, even with the frame-shaped iron back plate, a certain area preserved for the iron back plate is still needed to make sure the strength of the printed circuit board can be properly enhanced. In contrast, the server of the present invention utilizes the rigid rod fixed to the two sides of the printed circuit board to prevent the printed circuit board PA1 from being bended as being dropped or shocked. Because the reinforcement (i.e. the rigid rod) is connected to the heat sink which is fixed to the printed circuit board, both the heat sink and the rigid rod play the role to strengthen the printed circuit board. In addition, the external force applied to the two sides of the printed circuit board can further be dispersed through the rigid rod to the heat sink such that the strength of the printed circuit board can be significantly enhanced.

Moreover, because the rigid rod is fixed to the two sides of the printed circuit board through the two end fixing parts, the surface area needed for attaching the reinforcement can be significantly reduced. As the heat sink is concerned, because the heat sink is designed to meet the heat dissipation requirement of the printed circuit board, it should not be concerned as a device occupying additional surface area of the printed circuit board. Thus, in compared with the conventional art using the iron back plate to enhance the strength of the printed circuit board, the usage of the rigid rod together with the heat sink to enhance the strength of the printed circuit board in accordance with the present invention has an unpredictable function far more than merely a replacement of the iron back plate.

The detail description of the aforementioned preferred embodiments is for clarifying the feature and the spirit of the present invention. The present invention should not be limited by any of the exemplary embodiments described herein, but should be defined only in accordance with the following claims and their equivalents. Specifically, those skilled in the art should appreciate that they can readily use the disclosed conception and specific embodiments as a basis for designing or modifying other structures for carrying out the same purposes of the present invention without departing from the scope of the invention as defined by the appended claims.

We claim:

1. A server, comprising:
a printed circuit board, having a stress concentration zone and a stress dispersion zone around the stress concentration zone;
a heat sink, connected to the printed circuit board and located in the stress concentration zone; and
a rigid rod, connected to the heat sink, extended across the stress concentration zone, and being fixed to the stress dispersion zone of the printed circuit board.

2. The server of claim 1, wherein, the rigid rod having a rod body which is connected to the heat sink.

3. The server of claim 2, wherein the rod body is connected to the heat sink by welding.

4. The server of claim 2, wherein the rigid rod has two end fixing parts, the two end fixing parts are located on two ends of the rod body and fixed on the stress dispersion zone respectively.

5. The server of claim 4, wherein each of the two end fixing parts has a screw hole for fixing the two end fixing parts to the printed circuit board.

6. The server of claim 1, wherein the heat sink has a plurality of heat dissipation fins.

7. The server of claim 1, wherein the heat sink has a plurality of fixing holes for fixing the heat sink to the stress concentration zone of the printed circuit board.

8. The server of claim 1, wherein the heat sink is made of metal materials with a high thermal conductivity.
